(19) United States
(12) Patent Application Publication
(10) Pub. No.: US 2023/0184540 A1
(43) Pub. Date: Jun. 15, 2023

(54) SYSTEM FOR WAFER DECHUCKING AND HEALTH MONITORING

(71) Applicant: Applied Materials, Inc., Santa Clara, CA (US)

(72) Inventors: Yue Guo, Sunnyvale, CA (US); Yang Yang, Cupertino, CA (US); Kartik Ramaswamy, San Jose, CA (US)

(21) Appl. No.: 17/548,347

(22) Filed: Dec. 10, 2021

(51) Int. Cl. G01B 11/24; H01L 21/683; H01L 21/68; G01N 21/95

(52) U.S. Cl. CPC G01B 11/24; H01L 21/6833; H01L 21/68; G01N 21/9501

(57) ABSTRACT

Embodiments disclosed herein may further comprise a semiconductor processing tool. In an embodiment, the tool comprises a chamber with a chuck within the chamber. In an embodiment, the chuck is an electrostatic chuck. The tool may further comprise a laser configured to propagate a laser beam through a viewport through a chamber wall, with a beam splitter configured to separate the laser beam into a plurality of parallel beams. In an embodiment, the plurality of parallel beams are propagated towards the chuck. In an embodiment, the processing tool further comprises a camera configured to image the plurality of parallel beams, where the plurality of parallel beams are configured to reflect off a substrate on the chuck towards the camera.

### BACKGROUND

### 1) Field

Embodiments relate to the field of semiconductor manufacturing and, in particular, to a semiconductor processing tools that include apparatuses for measuring a curvature of a substrate secured on a chuck.

### 2) Description of Related Art

Plasma processes are often performed in vacuum environments by evacuating gas from a processing chamber. In such processes, a substrate (e.g., a wafer or the like) is placed on a chuck that is arranged on a stage of the plasma processing chamber. In some instances, the chuck is an electrostatic chuck. That is, an electrostatic force is used to secure the substrate to the stage. Electrostatic chucks can include a conductive sheet-type chuck electrode that is arranged between dielectric membranes. The chucking electrode is separated from the substrate by a thin layer of a dielectric material formed within the substrate support assembly. Typically, the bias electrode is formed of one or more electrically conductive parts, such as one or more metal meshes, foils, plates, combinations thereof, and the like.

When performing a plasma processing operation in the processing chamber, a voltage from a direct current (DC) voltage source is applied to the electrostatic source so that the substrate is chucked to the electrostatic chuck by a Coulomb force generated from the application of the DC voltage. After the plasma process is completed, voltage applied to the electrostatic chuck is turned off so that the substrate can be dechucked from the electrostatic chuck. In some instances, to dechuck the substrate, a discharge process is performed. The dechucking may involve introducing inert gas into the processing chamber, applying a voltage of the opposite polarity with respect to the voltage applied to the electrostatic chuck during the plasma process, and then turning off the voltage application so that the electric charges of the electrostatic chuck and the substrate may be discharged. Thereafter, lift pins are raised so that the substrate is lifted and dechucked from the electrostatic chuck.

### SUMMARY

Embodiments disclosed herein include a semiconductor processing tool. In an embodiment, the tool comprises a chamber, and a chuck within the chamber. In an embodiment, a laser is configured to propagate a laser beam through a viewport through a chamber wall. In an embodiment, a camera is configured to image the laser beam.

Embodiments further comprise a method of processing a substrate. In an embodiment, the method comprises measuring a baseline curvature of the substrate on a chuck in a processing tool. In an embodiment, the method further comprises applying a chucking force to the secure the substrate and processing the substrate in the processing tool. In an embodiment, the method further comprises releasing the chucking force, and raising the substrate with lift pins when a curvature of the substrate matches the baseline curvature.

Embodiments disclosed herein may further comprise a semiconductor processing tool. In an embodiment, the tool comprises a chamber with a chuck within the chamber. In an embodiment, the chuck is an electrostatic chuck. The tool may further comprise a laser configured to propagate a laser beam through a viewport through a chamber wall, with a beam splitter configured to separate the laser beam into a plurality of parallel beams. In an embodiment, the plurality of parallel beams are propagated towards the chuck. In an embodiment, the processing tool further comprises a camera configured to image the plurality of parallel beams, where the plurality of parallel beams are configured to reflect off a substrate on the chuck towards the camera.

### BRIEF DESCRIPTION OF THE DRAWINGS

FIG. 1A is a cross-sectional illustration of a plasma processing chamber with a substrate curvature detection system that uses two viewports, in accordance with an embodiment.

FIG. 1B is a cross-sectional illustration of a plasma processing chamber with a substrate curvature detection system that uses a single viewport, in accordance with an embodiment.

FIG. 1C, a system level diagram of a plasma processing chamber that uses a curvature detection system, in accordance with an embodiment.

FIG. 2A is a schematic of how the curvature detection system measures substrate curvature, in accordance with an embodiment.

FIG. 2B is a schematic of a curvature detection system measuring substrate curvature of a curved substrate, in accordance with an embodiment.

FIG. 2C is a schematic of a curvature detection system measuring substrate curvature of a curved substrate with an opposite curvature than the curvature shown in FIG. 2B, in accordance with an embodiment.

FIG. 3 is a process flow diagram of operations used to chuck and dechuck a substrate using a curvature detection system, in accordance with an embodiment.

FIG. 4A is a cross-sectional illustration of a curved substrate placed on an electrostatic chuck, in accordance with an embodiment.

FIG. 4B is a cross-sectional illustration of the curved substrate after it is secured to the electrostatic chuck, in accordance with an embodiment.

FIG. 4C is a cross-sectional illustration of the chucked curved substrate during a plasma process, in accordance with an embodiment.

FIG. 4D is a cross-sectional illustration of the curved substrate after the chucking force is released, in accordance with an embodiment.

FIG. 4E is a cross-sectional illustration of the curved substrate being lifted by lift pins, in accordance with an embodiment.

FIG. 5 is a process flow diagram of operations used to monitor the health of an electrostatic chuck, in accordance with an embodiment.

FIG. 6 illustrates a block diagram of an exemplary computer system that may be used in conjunction with a processing tool, in accordance with an embodiment.

### DETAILED DESCRIPTION

Systems described herein include a method and apparatus for measuring a curvature of a substrate secured on a chuck. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, electrostatic chucks are often used in semiconductor processing operations, such as plasma processing. Plasma processing may include etching processes or deposition processes. In an embodiment, the electrostatic chuck is used to secure a substrate during the processing. In some instances the substrate may be warped or otherwise curved. The warpage or curvature may be the result of stresses that are built up in the substrate during processing (e.g., the addition of various layers on the substrate may result in warpage due to differences in coefficient of thermal expansion (CTE), or the like). During chucking, the electrostatic force can be used to reduce or eliminate the warpage of the substrate in order to provide a flatter surface for processing. However, applying too much chucking force (i.e., over chucking) can result in damage to the substrate and/or the chuck. In some instances, the damage to the substrate may include total failure of the substrate resulting in fracture of the substrate. When the substrate breaks, substantial tool downtime is needed in order to retrieve the broken substrate and return the tool to an operating condition.

Accordingly, embodiments disclosed herein include apparatuses and methods in order to measure and monitor the warpage of the substrate. Particularly, the warpage of the substrate can be measured before processing, during process, and/or after processing. In one embodiment, the warpage before the substrate is chucked can be used as a baseline. The baseline curvature can then be used during a dechucking process. For example, the lift pins may not be activated until the curvature substantially matches the baseline curvature. In other embodiments, the curvature of the substrate during processing of the substrate may be used to monitor the health of the electrostatic chuck.

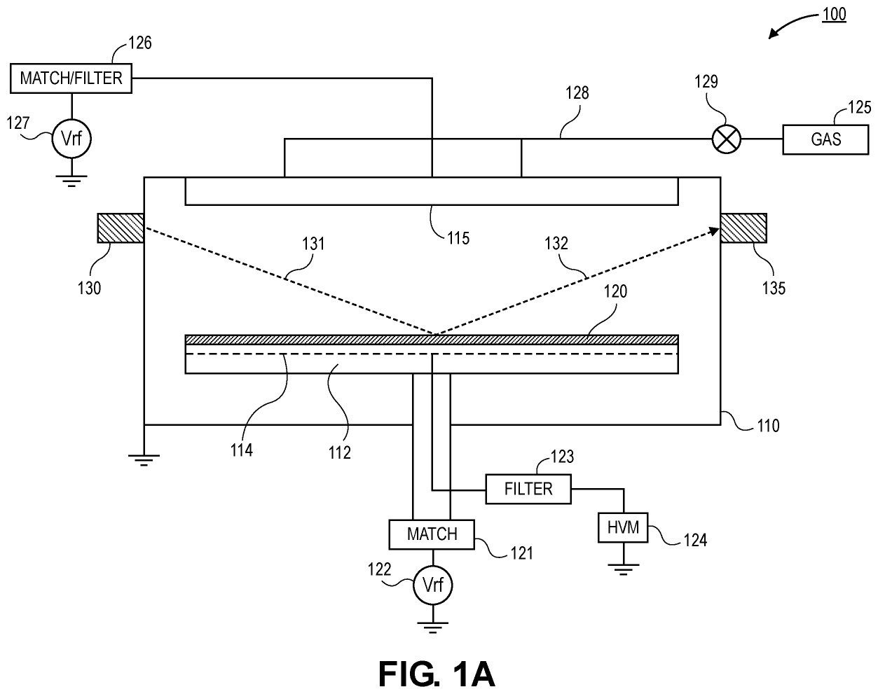

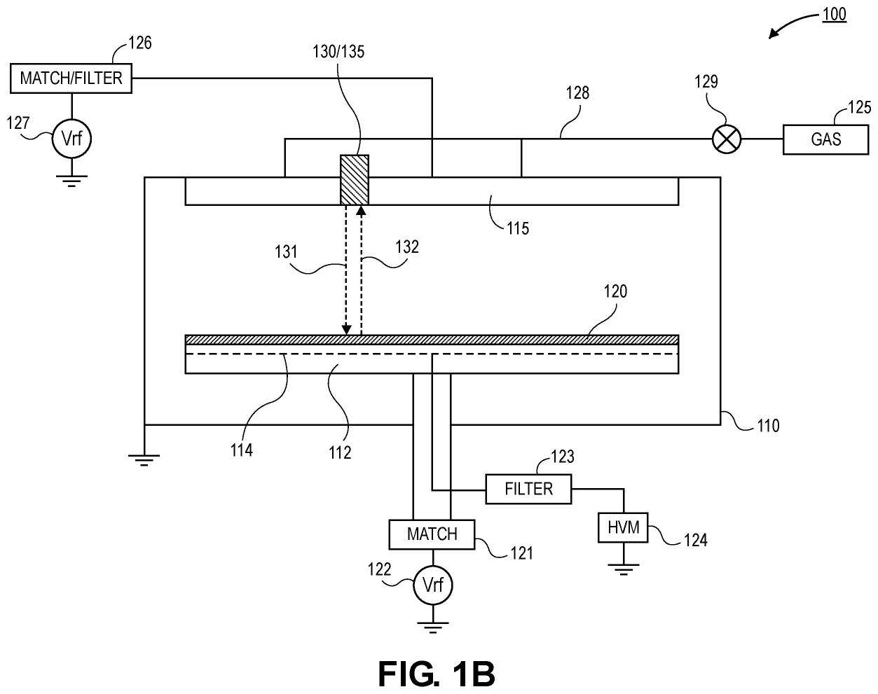

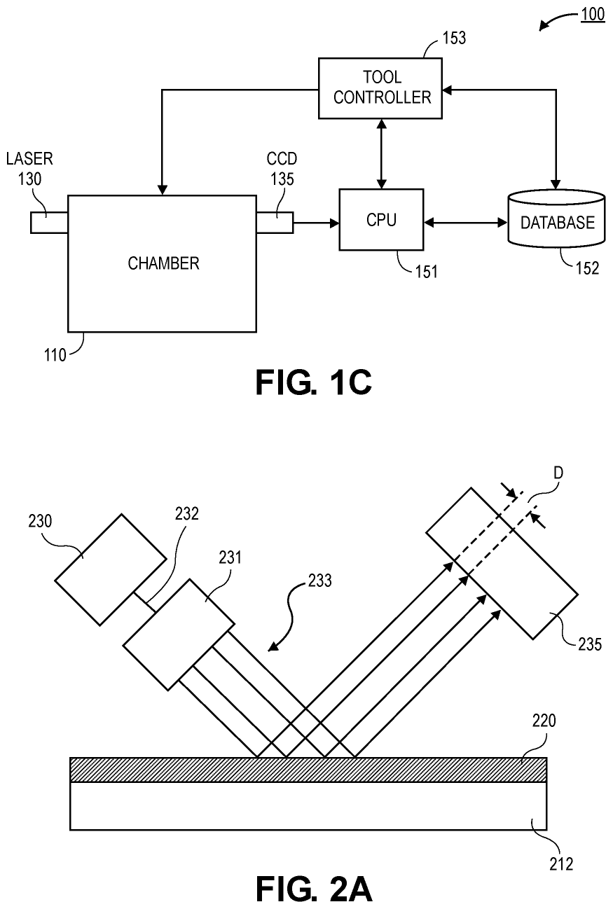

Referring now to FIG. 1A, a cross-sectional illustration a semiconductor processing tool 100 is shown, in accordance with an embodiment. In an embodiment, the tool 100 may be any type of tool typical of semiconductor processing environments. In a particular embodiment, the tool 100 is a plasma based tool. For example, the tool 100 may be a plasma etching or a plasma deposition tool. In an embodiment, the tool 100 may comprise a chamber 110. The chamber 110 may be grounded. In an embodiment, the chamber 110 is suitable for providing sub-atmospheric pressures. For example, a vacuum pump and/or exhaust system (not shown) may be coupled to the chamber 110.

In an embodiment, the tool 100 may comprise a showerhead 115. The showerhead 115 may have passages through which a gas from a gas source 125 may be flown. Processing gasses from the gas source 125 may pass through a valve 129 and tubing 128 to reach the showerhead 115. In an embodiment, the showerhead 115 may also be coupled to a power source 127 (e.g., an RF power source or a pulsed DC power source). That is, the showerhead 115 may function as a top electrode in some embodiments. In an embodiment, the power source 127 can be 13.56 MHz. The power source 127 may also be up to 60 MHz, 120 MHz, or even 162 MHz. Though, it is to be appreciated that lower or higher frequencies may also be used in some embodiments. The source power may be operated in a pulsed mode. The pulsing frequency is from 100 Hz to 5 kHz, and the duty cycle may range from 5% to 95%. A match/filter 126 may be provided between the power source 127 and the showerhead 115.

In an embodiment, a bias power 122 is applied to the bottom electrode. The bottom electrode may be part of the substrate support 112. The frequency range of the of the bias power 122 may be between 100 kHz and 20 MHz. The bias power 122 may be operated in either a continuous or a pulsed mode, including a pulsed DC mode. In some embodiment, there may be a third electrode at the edge of the cathode assembly for edge uniformity control. A third low frequency RF power can be delivered to the edge electrode and run at either a continuous or pulsing mode. For simplicity, the third electrode is not shown in FIG. 1A.

In an embodiment, the substrate support 112 may be a chuck. In a particular embodiment, the chuck may be an electrostatic chuck. As shown, an electrode 114 may be provided in the support 112. The electrode 114 may comprise metal meshes, foils, plates, combinations thereof, and the like. The electrode 114 may be separated from the substrate 120 by a dielectric layer. The electrode 114 may be electrically coupled to a filter 123 and a voltage source 124, such as a DC voltage source. As such, an electrostatic charge may build up between the substrate 120 and the electrode 114 to secure the substrate 120 to the support 112. In an embodiment, the substrate 120 may be any substrate material typical of semiconductor processing environments. In a particular embodiment, the substrate 120 may be a semiconductor wafer, such as a silicon wafer. In other embodiments, different semiconductor materials may be used for the substrate 120, or the substrate 120 may be a non-semiconductor material, such as glass, sapphire, quartz or the like.

In an embodiment, a substrate 120 curvature measurement system is included in the tool 100. In an embodiment, the curvature measurement system comprises a laser 130 and a camera 135. In an embodiment, the laser 130 and the camera 135 are positioned over viewports through a sidewall of the chamber 110. The laser 130 may be coupled to a first viewport and the camera 135 may be coupled to a second viewport. The first and second viewports may be on opposite surfaces of the chamber 110.

In an embodiment, the laser 130 may include a beam splitter (not shown). The beam splitter may take an incoming laser beam from the laser 130 and split it into a plurality of parallel beams with an equal intensity. In another embodiment, the laser 130 may comprise a plurality of laser sources, with a plurality of laser beams from the plurality of laser sources being parallel beams. The parallel beams are directed to a surface of the substrate 120 (as indicated by the line 131). The parallel beams are then reflected up to the camera 135 (as indicated by the line 132). The camera is configured to detect the spacing between the parallel beams. Changes to the spacing of the parallel beams at the camera can be used to determine curvature of the substrate 120. The curvature of the substrate 120 may then be used to calculate an amount of stress in the substrate 120. In an embodiment, the wavelength of the laser beam from the laser 130 may be between 405 nm and 660 nm. In an embodiment, the camera 135 may be a charge-coupled device (CCD) camera.

Since the laser 130 and the camera 135 are coupled into the chamber 110 through viewports, it is to be appreciated that there is no structural component of the curvature measurement system within the chamber 110. As such, it is possible to take curvature measurements at any time during the processing of a substrate 120. For example, curvature measurements may be made before chucking, after chucking, during substrate processing (e.g., during a plasma process), and/or during dechucking processes.

Referring now to FIG. 1B, a cross-sectional illustration of a semiconductor processing tool 100 is shown, in accordance with an additional embodiment. In an embodiment, the tool 100 in FIG. 1B may be substantially similar to the tool 100 in FIG. 1A, with the exception of the positioning of the curvature measurement system. Instead of being provided along sidewalls of the chamber 110, the curvature measurement system uses a viewport in the lid of the chamber 110. In an embodiment, an opening through the showerhead 115 may allow for the laser 130 and the camera 135 to look at the substrate 110 from above.

In an embodiment, the laser 130 and the camera 135 may be combined into a single component. Further, it is to be appreciated that the laser 130 may also comprise a beam splitter in order to split the laser beam from the laser 130 into a plurality of parallel beams. In the illustrated embodiment, the laser 130 and the camera 135 pass through the showerhead 115. In other embodiments, the laser 130 and the camera 135 may be outside of the chamber 110, and a hole may be provided through the showerhead 115 in order to allow laser beams to travel through the showerhead 115 for measuring the curvature of the substrate 120.

In the illustrated embodiment, the laser 130 and the camera 135 are offset from a center of the chamber 110. In other embodiments, the laser 130 and the camera 135 may be centered on the substrate 120. Though, it is to be appreciated that the laser 130 and the camera 135 may be located at any position along the top of the chamber 110. In yet another embodiment, two viewports may be provided through the top of the chamber 110, and the laser 130 may be coupled to the first viewport, and the camera 135 may be coupled to the second viewport.

Referring now to FIG. 1C, a schematic illustration of a semiconductor processing tool 100 is shown, in accordance with an additional embodiment. In an embodiment, the tool 100 comprises a chamber 110. The chamber 110 in FIG. 1C may be substantially similar to the chamber 110 described above. For example, the chamber 110 may include a substrate support (with an electrostatic chuck), a showerhead, and other components described above. As shown, a laser 130 and a camera 135 may be provided on opposite sides of the chamber 110.

In an embodiment, the camera 135 (e.g., a CCD camera) may be coupled to a computer (CPU) 151 or any other type of processor. The computer 151 may be receive image data from the camera 135. The image data may be processed to determine a spacing between the parallel laser beams. The spacing between the parallel laser beams may be used to determine a curvature of the substrate, and the curvature may be used to calculate a stress of the substrate.

In an embodiment, the curvature and/or stress information may be provided to a database 152. The database 152 may store curvature and/or stress information of a particular substrate for future use. For example, as will be described in greater detail below, a baseline curvature may be stored in the database 152 and used during a dechucking process. When the substrate curvature substantially matches the baseline curvature, the dechucking is complete and the lift pins may be activated. The database 152 may also store curvature information that can be used to monitor substrate health and/or electrostatic chuck health.

In an embodiment, the database 152 and the computer 151 may both be coupled to a tool controller 153. The tool controller 153 may use data directly from the computer 151 to control processing conditions within the chamber 110. For example, the tool controller 153 may change a chucking voltage in order to modify the curvature of the substrate. The tool controller 153 may also use stored data from the database 152 in order to control processing conditions within the chamber 110.

In an embodiment, the tool controller 153 may control the processing conditions within the chamber 110 using machine learning and/or artificial intelligence. For example, incoming substrate curvature measurements may be fed into a chucking model in the tool controller 153. The chucking model may use the incoming curvature measurements to determine a chucking voltage suitable for securing the substrate and reducing the curvature of the substrate. The chucking model may also include a dechucking process that can be implemented to reduce the risk of damaging the substrate.

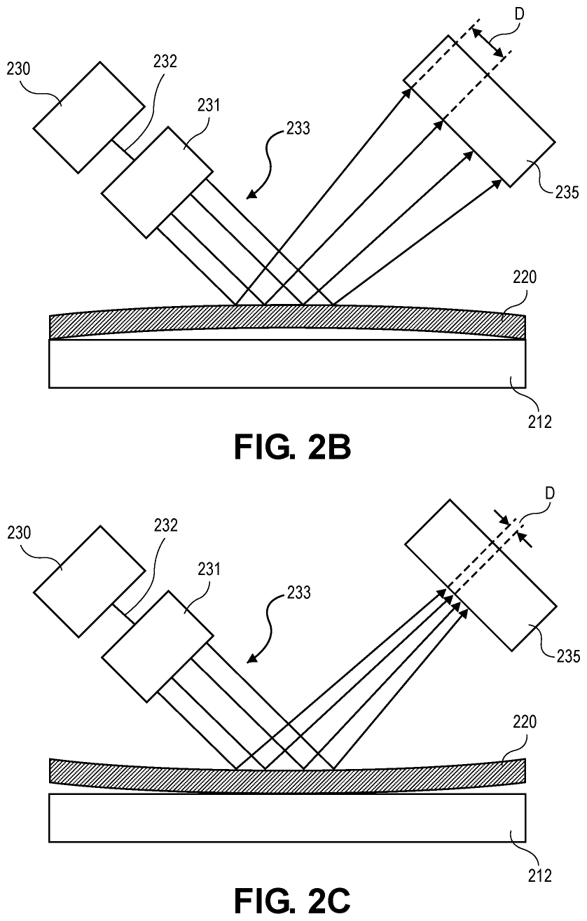

Referring now to FIGS. 2A-2C, a series of schematic illustrations depicting the measurement process for substrates with different curvatures is shown, in accordance with an embodiment. In FIGS. 2A-2C, the surrounding chamber components (e.g., chamber walls, showerhead, etc.) are omitted for simplicity. However, it is to be appreciated that the laser beams may pass through viewports in a chamber sidewall or a chamber lid. That is, the laser 230, the beam splitter 231, and the camera 235 may be outside of the chamber, as shown in the embodiments described above.

Referring now to FIG. 2A, a schematic illustration of a curvature measurement system measuring the curvature of a substantially flat substrate 220 is shown, in accordance with an embodiment. In an embodiment, the substrate 220 may be provided on a substrate support 212, such as an electrostatic chuck, or the like. The curvature measurement system may comprise a laser 230. The laser 230 may emit a laser beam 232. The laser beam 232 may be between 405 nm and 660 nm. In an embodiment, the laser beam 232 may be directed into a beam splitter 231. The beam splitter 231 may split the incoming laser beam 232 into a plurality of parallel beams 233. In the illustrated embodiment, four beams 233 are shown. Though, it is to be appreciated that the beam splitter 231 may provide two or more beams 233.

As shown in FIG. 2A, the parallel beams 233 propagate towards a surface of the substrate 220. The parallel beams 233 then reflect off of the surface of the substrate 220 and are directed towards the camera 235. In an embodiment, the camera 235 detects the relative positioning between the beams 233. For example, the camera 235 (and an associated computing system, such as computer 151 in FIG. 1C) calculate a spacing D between the beams 233 at the camera. When the orientation of the beams 233 before they interact with the substrate 220 is known, the spacing D can be used to determine an amount of curvature of the substrate. That is, as the curvature of the substrate 220 changes, so does the spacing D between the beams at the camera 235.

Referring now to 2B, a schematic illustration of a curvature measurement system measuring the curvature of a curved substrate 220 is shown, in accordance with an embodiment. As shown, the top surface of the substrate 220 is convex. In such an embodiment, the reflection of the parallel beams 233 may result in a spreading of the beams 233 at the camera 235. As such, the spacing D may be greater than the spacing D shown in FIG. 2A with a flat substrate 220.

Referring now to FIG. 2C, a schematic illustration of a curvature measurement system measuring the curvature of a curved substrate 220 is shown, in accordance with an additional embodiment. As shown, the top surface of the substrate 220 is concave. In such an embodiment, the reflection of the parallel beams 233 may result in a contraction of the beams 233 at the camera 235. As such, the spacing D may be less than the spacing D shown in FIG. 2A with a flat substrate.

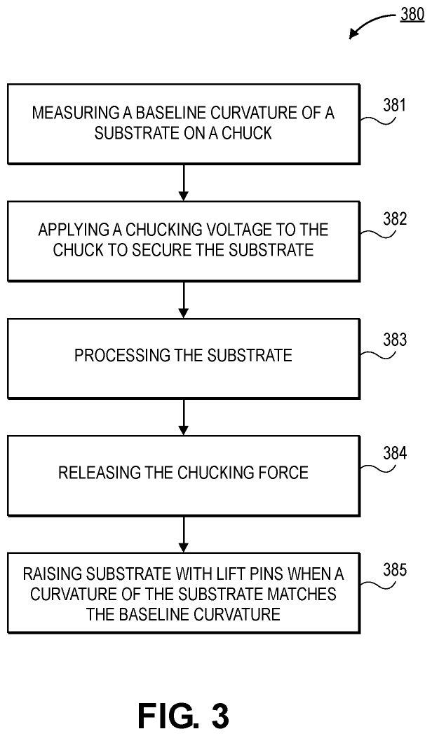

Referring now to FIG. 3, a flow diagram of a process 380 for processing a substrate is shown, in accordance with an embodiment. In an embodiment, the processing of the substrate includes a chucking operation and a dechucking operation. The use of a curvature measurement system may be used in order to determine when it is safe to use the lift pins to raise the substrate after the dechucking operation, as will be described in greater detail below.

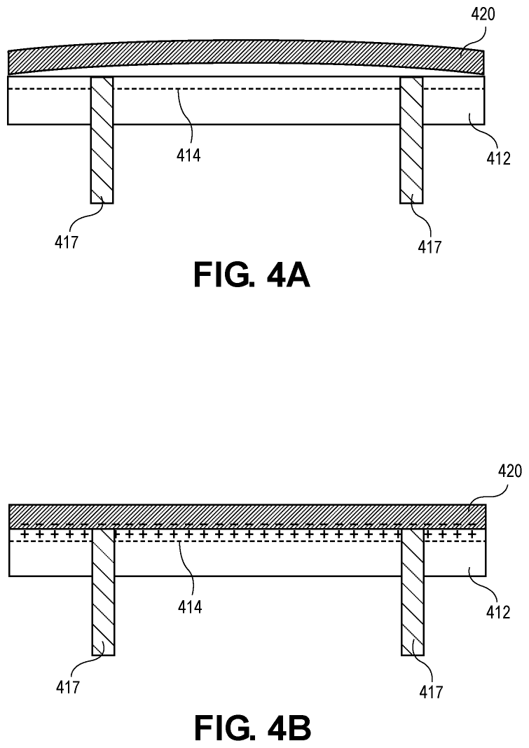

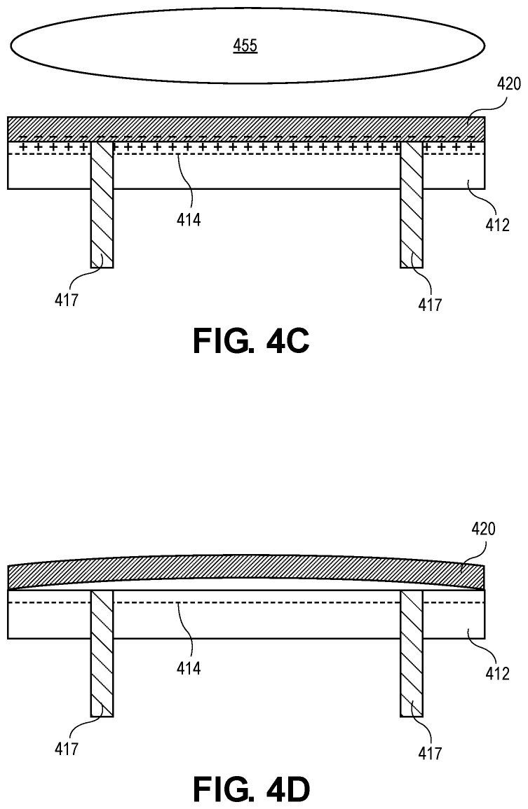

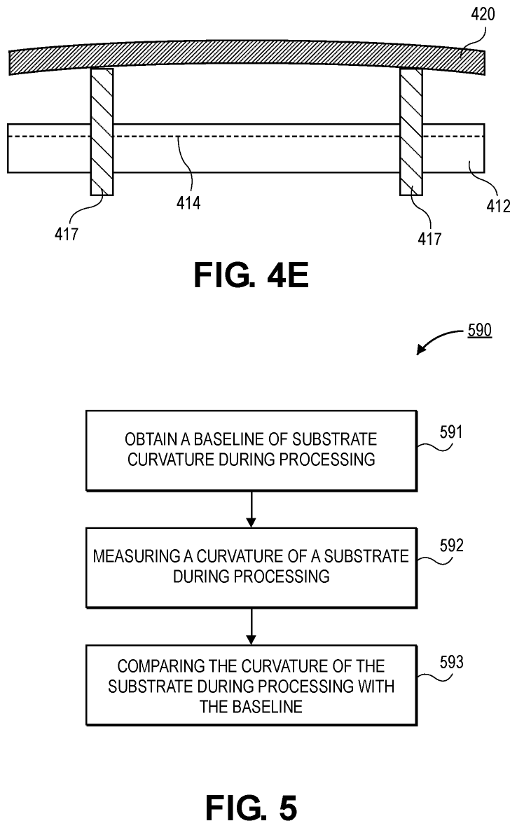

In an embodiment, the process 380 begins with operation 381, which comprises measuring a baseline curvature of a substrate on a chuck. FIG. 4A provides a cross-sectional illustration of operation 381. As shown, a substrate 420 is supported on a substrate support 412. Lift pins 417 have been fully retracted. Additionally, an electrostatic chucking electrode 414 is not activated. That is, the substrate 420 is supported by the substrate support 412, but is not electrostatically attracted to the support 412. In an embodiment, the baseline curvature may be measured with a curvature measurement system, such as those described in greater detail above. The baseline curvature may be stored in a database (such as database 152 described above).

Referring back to FIG. 3, process 380 continues with operation 382, which comprises applying a chucking voltage to the chucking electrode 414 to secure the substrate 420 to the substrate support 412. As shown in FIG. 4B, the chucking voltage on the chucking electrode 414 results in opposing polarities being applied to the substrate 420 and the top surface of the substrate support 412 in order to electrostatically couple the substrate 420 to the substrate support 412. In an embodiment, the chucking force may also result in a decrease in the curvature of the substrate 420. In the illustrated embodiment, the curvature of the substrate 420 is reduced, but not entirely eliminated. In other embodiments, the chucking force may substantially eliminate the curvature on the substrate 420. In an embodiment, curvature of the substrate 420 after chucking may be measured with a curvature measurement system, such as those described in greater detail above.

Referring back to FIG. 3, process 380 may continue with operation 383, which comprises processing the substrate 420. As shown in FIG. 4C, a plasma 455 may be provided within the chamber over the substrate 420. The processing may include any plasma process, such as a deposition or etching process. While described as being a plasma process, it is to be appreciated that embodiments may also include processing the substrate 420 without the use of a plasma. In an embodiment, one or more measurements of the curvature of the substrate 420 may be made during the processing. Particularly, it is to be appreciated that the curvature measurement process does not interact with the plasma, so the measurement does not alter the processing of the substrate 420. The measurement of the curvature of the substrate 420 during the processing may be used to diagnose substrate health and/or electrostatic chuck health.

Referring back to FIG. 3, process 380 may continue with operation 384 which comprises releasing the chucking force. In an embodiment, releasing the chucking force may include introducing an inert gas into the processing chamber, applying a voltage of the opposite polarity with respect to the voltage applied to the chuck electrode 414 during the plasma process, and then turning off the voltage application so that the electric charges of the electrostatic chuck and the substrate may be discharged. As shown in FIG. 4D, releasing the chucking force may allow the substrate 420 to return to a curvature similar to the baseline curvature. In an embodiment, operation 384 may further comprise optimizing and maintaining a dechucking voltage that balances the residual charge accumulated on the substrate, and not lifting the substrate until the measured curvature matches the baseline curvature. That is, it may not be possible to completely discharge the substrate, and the residual charge needs to be balanced by applying and maintaining a dechucking voltage while the substrate is lifted.

Referring back to FIG. 3, process 380 may continue with operation 385, which comprises raising the substrate with lift pins when a curvature of the substrate substantially matches the baseline curvature. As shown in FIG. 4E, the lift pins 417 extend up to lift the substrate 420 off of the substrate support 412. In an embodiment, the curvature of the substrate 420 is measured with a curvature measurement system during the dechucking process. When the curvature of the substrate 420 substantially matches the baseline curvature, it can be presumed that the chucking force has been substantially released. That indicates that the substrate 420 may be safely lifted with the lift pins 417. If the lift pins 417 were to be activated before the substrate is fully dechucked, the substrate 420 and/or the lift pins 417 may be damaged.

Referring now to FIG. 5, a flow diagram of a process 590 for monitoring the health of a chucking system and/or the condition of a substrate is shown, in accordance with an embodiment. In an embodiment, the process 590 begins with operation 591, which comprises obtaining a baseline of substrate curvature during the processing of a substrate. In an embodiment, the baseline substrate curvature may include a plurality of measurements taken during the processing of the substrate. The baseline measurement may be made on the first substrate in a lot. Alternatively, the baseline measurement may be made after the chucking system is replaced or repaired. The baseline measurement may be made with a curvature measurement system similar to those described in greater detail above. For example, a beam splitter may split a laser beam into a plurality of parallel beams that reflect off of a surface of the substrate and are detected by a camera. In an embodiment, the baseline measurement may be stored in a database (such as database 152) for future use.

In an embodiment, process 590 may continue with operation 592, which comprises measuring a curvature of a substrate during processing of the substrate. In an embodiment, the curvature measurement (or measurements) may be made using a curvature measurement system similar to those described in greater detail above. For example, a beam splitter may split a laser beam into a plurality of parallel beams that reflect off of a surface of the substrate and are detected by a camera. In an embodiment, the processing of the substrate may include a plasma. In other embodiments, the processing may be implemented without a plasma. However, it is to be appreciated that the measurement system does not interfere or otherwise interact with the processing conditions during the measurement of the curvature of the substrate.

In an embodiment, process 590 may continue with operation 593, which comprises comparing the curvature of the substrate during the processing with the baseline measurement. In an embodiment, when the measured curvature matches the baseline measurement, then it is to be presumed that the chuck is operating as expected. Additionally, it may be presumed that the substrate is undergoing stresses similar to those of the baseline substrate. When the measured curvature is different than the baseline measurement, then it can be presumed that the chuck is operating sub-optimally, or that the substrate is deviating from acceptable stress conditions. When an abnormality is detected in the chucking performance, preventative maintenance can be performed or the chucking features can be replaced. When the stress in the substrate is different than in the baseline substrate, the substrate can undergo further inspection in order to determine if the damage is repairable.

Ultimately, the processes 380 and 590 result in significant benefits. For example, the in situ substrate curvature measurement allows for substrate damage and chucking status to be measured in real time without disturbing a plasma. Additionally, such processes can effectively predict and detect early signs for substrate breakage and fatigue by evaluating substrate stress distributions during process runs. Another advantage is that the measured curvature can be used as a powerful parameter for process optimization and diagnostics. Also, the proposed systems and methods can help to efficiently reduce chamber downtime by avoiding unwanted situations with unsafe and/or abnormal substrate curvatures and stresses.

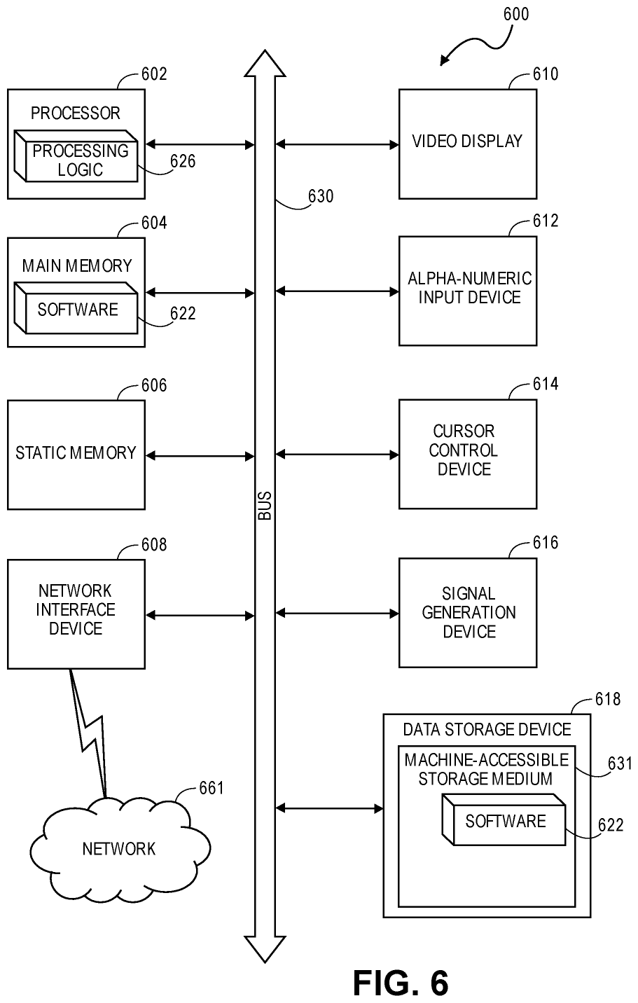

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 632 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 620 via the system network interface device 608. In an embodiment, the network interface device 608 may operate using RF coupling, optical coupling, acoustic coupling, or inductive coupling.

While the machine-accessible storage medium 632 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

1. A semiconductor processing tool, comprising:
a chamber having a chamber lid over a chamber sidewall;
a chuck within the chamber;
a laser configured to propagate a laser beam through a viewport through the chamber sidewall; and
a camera configured to image the laser beam.

2. The semiconductor processing tool of claim 1, further comprising:
a beam splitter to split the laser beam into a plurality of parallel beams.

3. The semiconductor processing tool of claim 2, wherein the plurality of parallel beams are propagated towards the chuck.

4. The semiconductor processing tool of claim 3, wherein a substrate is on the chuck, and wherein the plurality of parallel beams reflect off the substrate towards the camera.

5. The semiconductor processing tool of claim 4, wherein the camera is configured to detect a distance between the parallel beams.

6. The semiconductor processing tool of claim 2, wherein the plurality of parallel beams includes four or more beams.

7. The semiconductor processing tool of claim 1, wherein the camera is configured to image the laser beam through a second viewport through the chamber sidewall.

8. The semiconductor processing tool of claim 1, wherein the semiconductor processing tool is a plasma processing tool.

9. The semiconductor processing tool of claim 8, wherein the laser and the camera are configured to operate during a plasma process in the plasma processing tool.

10. The semiconductor processing tool of claim 1, wherein the chuck is an electrostatic chuck.

11. A method of processing a substrate, comprising:
measuring a baseline curvature of the substrate on a chuck in a processing tool;
applying a chucking force to secure the substrate;
processing the substrate in the processing tool;
releasing the chucking force; and
raising the substrate with lift pins when a curvature of the substrate matches the baseline curvature.

12. The method of claim 11, wherein the curvature of the substrate is measured with a laser and a camera.

13. The method of claim 12, wherein a laser beam from the laser is split into a plurality of parallel beams directed to the substrate, and wherein the camera detects a spacing between the parallel beams.

14. The method of claim 13, wherein the spacing between the parallel beams is correlated with the curvature of the substrate.

15. The method of claim 12, wherein a laser beam from the laser passes through viewports through a wall of the processing tool.

16. The method of claim 12, further comprising:
measuring a curvature of the substrate during the processing of the substrate in the processing tool.

17. The method of claim 16, wherein the curvature of the substrate during processing is compared to a processing baseline curvature, and wherein a chuck health is determined by the comparison.

18. A semiconductor processing tool, comprising:
a chamber having a chamber lid over a chamber sidewall;
a chuck within the chamber, wherein the chuck is an electrostatic chuck;
a laser configured to propagate a laser beam through a viewport through the chamber sidewall;
a beam splitter configured to separate the laser beam into a plurality of parallel beams, wherein the plurality of parallel beams are propagated towards the chuck; and
a camera configured to image the plurality of parallel beams, wherein the plurality of parallel beams are configured to reflect off a substrate on the chuck towards the camera.

19. The semiconductor processing tool of claim 18, wherein the semiconductor processing tool is a plasma processing tool.

20. The semiconductor processing tool of claim 19, wherein the camera is a charge-coupled device (CCD) camera.
